(19) United States
(12) Patent Application Publication
(10) Pub. No.: US 2026/0230049 A1
(43) Pub. Date: Aug. 6, 2026

(54) Gain amplifier for re-driver circuit using all-CMOS process

(71) Applicant: NOVATEK Microelectronics Corp., Hsin-Chu (TW)

(72) Inventors: Chun-Chi Chang, Hsinchu City (TW); Tung-Cheng Hsin, Hsinchu City (TW)

(73) Assignee: NOVATEK Microelectronics Corp., Hsin-Chu (TW)

(21) Appl. No.: 19/208,578

(22) Filed: May 14, 2025

Related U.S. Application Data
(60) Provisional application No. 63/754,580, filed on Feb. 6, 2025.

(51) Int. Cl. H03F 3/45

(52) U.S. Cl. CPC H03F 3/45179

(57) ABSTRACT

A gain amplifier includes a gain stage, a transimpedance amplifier stage and a feedback stage. The gain stage includes two resistors, two PMOS transistors and two NMOS transistors. A first terminal of the first PMOS transistor and a first terminal of the second PMOS transistor are connected to the first resistor. A first terminal of the first NMOS transistor and a first terminal of the second NMOS transistor are connected to the second resistor. A second terminal of the first PMOS transistor is connected to a second terminal of the first NMOS transistor. A gate terminal of the first PMOS transistor is connected to a gate terminal of the first NMOS transistor. A second terminal of the second PMOS transistor is connected to a second terminal of the second NMOS transistor. A gate terminal of the second PMOS transistor is connected to a gate terminal of the second NMOS transistor.

### CROSS REFERENCE TO RELATED APPLICATIONS

This application claims the benefit of U.S. Provisional Application No. 63/754,580, filed on Feb. 6, 2025. The content of the application is incorporated herein by reference.

### BACKGROUND OF THE INVENTION

### 1. Field of the Invention

The present invention relates to a variable gain amplifier (VGA), and more particularly, to a VGA that could be implemented in a re-driver circuit.

### 2. Description of the Prior Art

With the explosion of information nowadays, the amount of data transmitted in an electronic system is getting larger and larger, and the transmission rate is getting faster and faster. Signals in high-speed transmission easily attenuate after propagating a certain distance, and thus there is a need to develop a re-driver (or re-timer) to be used as a repeater deployed on the signal transmission path, to compensate for the attenuations of the high-speed signals. A linear re-driver can provide a higher linearity for the signals, and thus is usually used to realize the re-driver circuit.

However, the linear re-driver has a high demand for swing linearity. Traditionally, the linear re-driver is mostly implemented by using the bipolar complementary metal-oxide semiconductor (BiCMOS) process to gain the benefits of high transconductance (gm) of bipolar junction transistor (BJT) devices. However, the BJT has a disadvantage that its voltage headroom requirement is much greater than the voltage headroom requirement of a complementary metal-oxide semiconductor (CMOS) device. This is contrary to the trends of pursuing low voltage supply and low power consumption. In addition, the BiCMOS process uses both BJT and CMOS transistors in the circuit, which is accompanied by a higher circuit cost than the all-CMOS process.

### SUMMARY OF THE INVENTION

It is therefore an objective of the present invention to provide a novel variable gain amplifier (VGA) of a re-driver circuit implemented with the all-CMOS process, in order to solve the abovementioned problems.

An embodiment of the present invention discloses a gain amplifier, which comprises a gain stage, a transimpedance amplifier (TIA) stage and a feedback stage. The TIA stage is coupled to the gain stage. The feedback stage is coupled to the gain stage and the TIA stage. The gain stage comprises a first resistor, a second resistor, a first PMOS transistor, a first NMOS transistor, a second PMOS transistor and a second NMOS transistor. The first PMOS transistor has a first terminal, a second terminal and a gate terminal, wherein the first terminal is connected to the first resistor. The first NMOS transistor has a first terminal, a second terminal and a gate terminal, wherein the first terminal is connected to the second resistor, the second terminal is connected to the second terminal of the first PMOS transistor, and the gate terminal is connected to the gate terminal of the first PMOS transistor. The second PMOS transistor has a first terminal, a second terminal and a gate terminal, wherein the first terminal is connected to the first resistor. The second NMOS transistor has a first terminal, a second terminal and a gate terminal, wherein the first terminal is connected to the second resistor, the second terminal is connected to the second terminal of the second PMOS transistor, and the gate terminal is connected to the gate terminal of the second PMOS transistor.

Another embodiment of the present invention discloses a re-driver circuit, which comprises an equalizer, a gain amplifier and a transmitter. The gain amplifier is coupled to the equalizer, and the transmitter is coupled to the gain amplifier. The gain amplifier comprises a gain stage, a TIA stage and a feedback stage. The TIA stage is coupled to the gain stage. The feedback stage is coupled to the gain stage and the TIA stage. The gain stage comprises a first resistor, a second resistor, a first PMOS transistor, a first NMOS transistor, a second PMOS transistor and a second NMOS transistor. The first PMOS transistor has a first terminal, a second terminal and a gate terminal, wherein the first terminal is connected to the first resistor. The first NMOS transistor has a first terminal, a second terminal and a gate terminal, wherein the first terminal is connected to the second resistor, the second terminal is connected to the second terminal of the first PMOS transistor, and the gate terminal is connected to the gate terminal of the first PMOS transistor. The second PMOS transistor has a first terminal, a second terminal and a gate terminal, wherein the first terminal is connected to the first resistor. The second NMOS transistor has a first terminal, a second terminal and a gate terminal, wherein the first terminal is connected to the second resistor, the second terminal is connected to the second terminal of the second PMOS transistor, and the gate terminal is connected to the gate terminal of the second PMOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a general VGA.

FIG. 2 is a schematic diagram of a re-driver circuit according to an embodiment of the present invention.

FIG. 3 illustrates a detailed implementation of the VGA according to an embodiment of the present invention.

FIG. 4 illustrates a detailed implementation of the gain stage and the feedback stage according to an embodiment of the present invention.

FIG. 5 illustrates a detailed implementation of the TIA stage according to an embodiment of the present invention.

FIG. 6 illustrates the transconductance values of the PMOS transistors and the NMOS transistors over a voltage range of the input signals.

FIG. 7 illustrates the gain stage and the feedback stage implemented with high-voltage devices and low-voltage devices.

FIG. 8 illustrates the TIA stage implemented with high-voltage devices and low-voltage devices.

### DETAILED DESCRIPTION

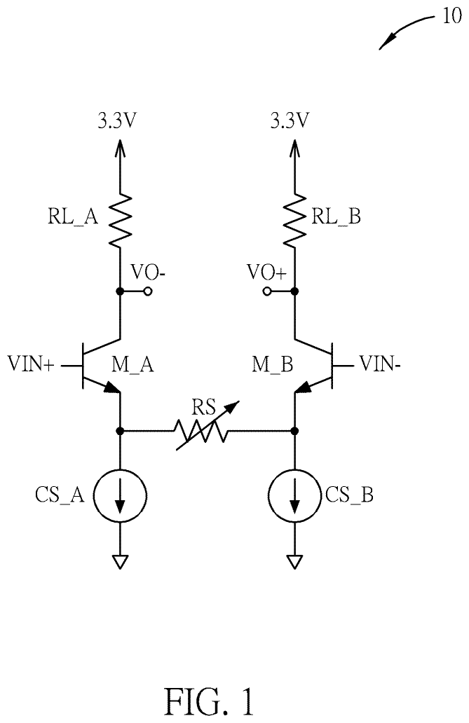

FIG. 1 is a schematic diagram of a general variable gain amplifier (VGA) 10. The VGA 10 includes two current sources CS_A and CS_B, two load resistors RL_A and RL_B, two bipolar junction transistors (BJTs) M_A and M_B, and a variable resistor RS. The BJTs M_A and M_B are input transistors for receiving differential input signals VIN+ and VIN− to generate differential output signals VO+ and VO−. The VGA 10 may provide a high gain for high-speed signals. The gain of the VGA 10 may be calculated as follows:

$$Gain = \frac{{g}_{m}}{1 + {g}_{m} {R}_{S}} \times {R}_{L} ; \qquad ( 1 )$$

where R_{L} is the resistance value of the load resistors RL_A and RL_B, R_{S} is the resistance value of the variable resistor RS, and gₘ is the transconductance value of the BJTs M_A and M_B.

In general, the current sources CS_A and CS_B are implemented with complementary metal-oxide semiconductor (CMOS) transistors; hence, the VGA 10 is implemented with the bipolar complementary metal-oxide semiconductor (BiCMOS) process. Due to the high transconductance gₘ of the BJTs M_A and M_B, the VGA 10 is suitable for a high gain application such as the linear re-driver. However, as mentioned above, the BiCMOS process is accompanied by a higher circuit cost, and the BJTs M_A and M_B have a larger voltage headroom requirement, resulting in a constraint on the supply voltage of the VGA 10. For example, as shown in FIG. 1, the supply voltage is required to be greater than or equal to 3.3V, which consumes more power and is not conducive in the applications of advanced processes.

Therefore, the present invention provides a novel structure of a VGA and related re-driver circuit by using the all-CMOS process, where all transistor devices are CMOS transistors. This prevents the voltage headroom problem of BJTs, so as to support a lower supply voltage and achieve a wide supply voltage range. The circuit cost may also be reduced without the usage of BJTs. In addition, through appropriate circuit design, high bandwidth and high swing linearity may also be achieved.

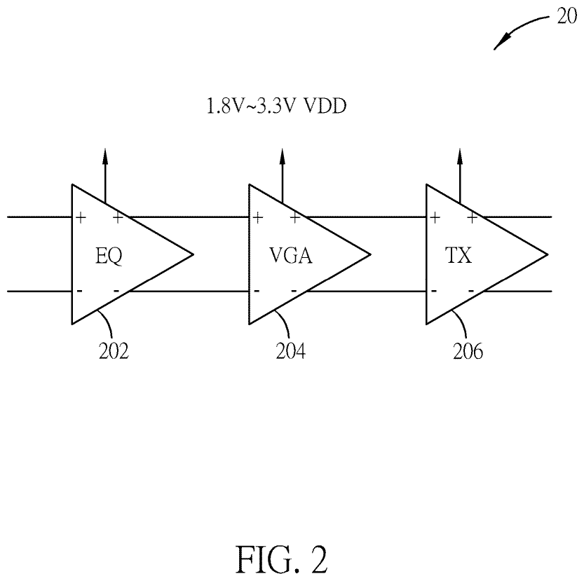

FIG. 2 is a schematic diagram of a re-driver circuit 20 according to an embodiment of the present invention. The re-driver circuit 20 includes an equalizer (EQ) 202, a VGA 204 and a transmitter (TX) 206. The signals received by the re-driver circuit 20 are first processed by the equalizer 202, which is configured to compensate for high frequency attenuations on the received signals. The VGA 204 is configured to amplify the signal swing and maintain the linearity of the signals. After the compensation and amplification operations, the transmitter 206 outputs the signals with sufficient driving capability. The design of the transmitter 206 should also be adapted to the requirement of impedance matching.

As shown in FIG. 2, the re-driver circuit 20 may support a wide range of supply voltage VDD from 1.8V to 3.3V. Note that a VGA implemented in the re-driver with the BiCMOS process, such as the VGA 10 shown in FIG. 1, can only support a higher supply voltage such as 3.3V due to its voltage headroom problem. In comparison, the VGA 204 and the re-driver circuit 20 of the present invention may be implemented in the all-CMOS process, and thus could support a lower supply voltage and a wider supply voltage range.

In order to achieve high signal linearity, the present invention provides appropriate circuit design in the re-driver circuit 20. In general, the equalizer 202, which may be a continuous time linear equalizer (CTLE), for example, usually applies source degeneration to compensation for the high frequency attenuation of the signals, where the source degeneration with large resistance may improve the signal linearity; hence, there is no linearity problem in the equalizer 202. However, the VGA 204 is requested to provide a high direct current (DC) gain and thus the strength of source degeneration is limited, such that the VGA 204 usually has the linearity problem to be solved, especially when the signal swing is large.

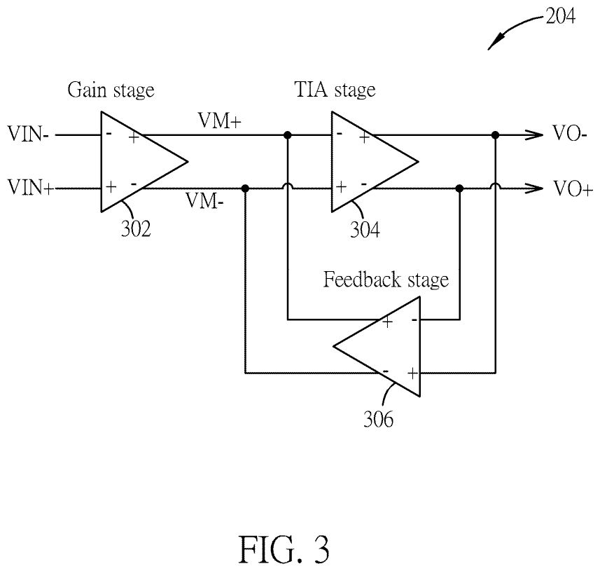

The present invention provides a novel VGA structure to improve the signal linearity. FIG. 3 illustrates a detailed implementation of the VGA 204 according to an embodiment of the present invention. The VGA 204 includes a gain stage 302, a transimpedance amplifier (TIA) stage 304 and a feedback stage 306.

The gain stage 302 may receive differential input signals VIN+ and VIN− to generate intermediate signals VM+ and VM−. The gain stage 302 is a main circuit stage of the VGA 204, to provide high gain for amplifying the signals.

The TIA stage 304 may receive the intermediate signals VM+ and VM− to generate output signals VO+ and VO−. More specifically, the positive input terminal of the TIA stage 304 is coupled to the negative output terminal of the gain stage 302 to receive the intermediate signal VM−, and the negative input terminal of the TIA stage 304 is coupled to the positive output terminal of the gain stage 302 to receive the intermediate signal VM+. The TIA stage 304 is used for enhancing the gain bandwidth, and also providing stable signals for the gain stage 302, i.e., stabilizing the voltages of the intermediate signals VM+ and VM− at the output terminals of the gain stage 302. Note that the gain stage 302 aims at providing a high gain, and thus the intermediate signals VM+ and VM− output by the gain stage 302 may possess large signal swing. Therefore, with the control of the TIA stage 304, the intermediate signals VM+ and VM− may be kept at a stable common mode voltage, thereby improving the gain linearity and increasing the signal bandwidth.

The feedback stage 306 may be coupled to the gain stage 302 and the TIA stage 304 to form a feedback path. More specifically, the positive input terminal of the feedback stage 306 is coupled to the positive output terminal of the TIA stage 304, and the negative input terminal of the feedback stage 306 is coupled to the negative output terminal of the TIA stage 304. In addition, the positive output terminal of the feedback stage 306 is coupled to the negative input terminal of the TIA stage 304, and the negative output terminal of the feedback stage 306 is coupled to the positive input terminal of the TIA stage 304. The deployment of the feedback stage 306 may also increase the signal bandwidth and improve the gain linearity.

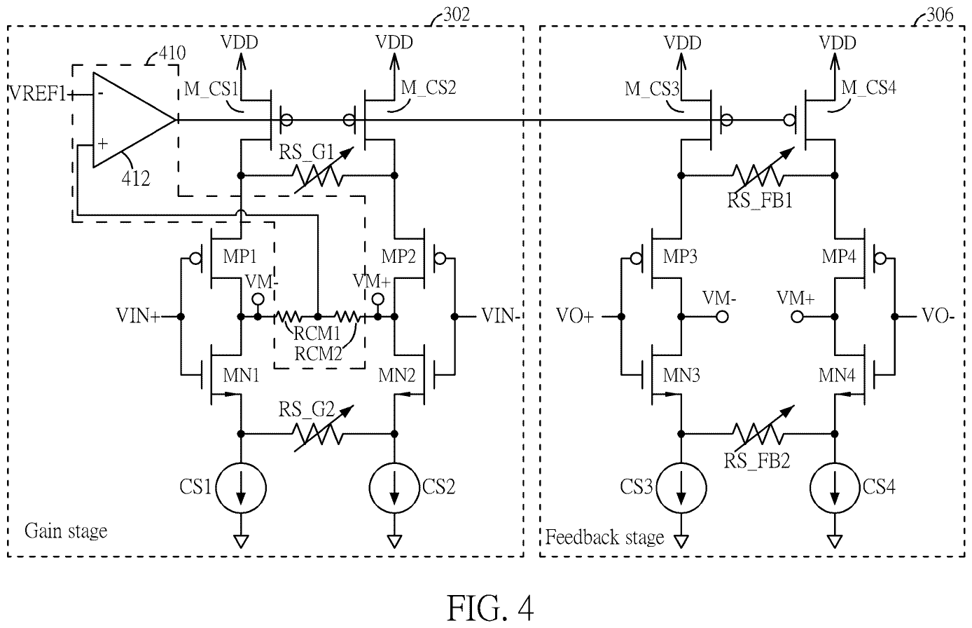

FIG. 4 illustrates a detailed implementation of the gain stage 302 and the feedback stage 306 according to an embodiment of the present invention. The gain stage 302 includes two PMOS transistors MP1 and MP2 and two NMOS transistors MN1 and MN2 used to forward signals. In detail, the gate terminal of the PMOS transistor MP1 and the gate terminal of the NMOS transistor MN1 are connected together to receive the input signal VIN+, and the gate terminal of the PMOS transistor MP2 and the gate terminal of the NMOS transistor MN2 are connected together to receive the input signal VIN−. In addition, the drain terminal of the PMOS transistor MP1 and the drain terminal of the NMOS transistor MN1 are connected together to output the intermediate signal VM−, and the drain terminal of the PMOS transistor MP2 and the drain terminal of the NMOS transistor MN2 are connected together to output the intermediate signal VM+.

As shown in FIG. 4, the gain stage 302 further includes a pair of PMOS transistors M_CS1 and M_CS2, a pair of current sources CS1 and CS2, two source degeneration resistors RS_G1 and RS_G2, and a common mode control circuit 410. The source terminal of the PMOS transistor MP1 is further connected to a terminal of the source degeneration resistor RS_G1, and the source terminal of the PMOS transistor MP2 is further connected to another terminal of the source degeneration resistor RS_G1. The source terminal of the NMOS transistor MN1 is further connected to a terminal of the source degeneration resistor RS_G2, and the source terminal of the NMOS transistor MN2 is further connected to another terminal of the source degeneration resistor RS_G2. In one or some embodiments, the source degeneration resistors RS_G1 and RS_G2 may be variable resistors, and thus their resistance values may be adjusted or switched appropriately to determine the gain of the gain stage 302, thereby determining the gain of the VGA 204. The PMOS transistor M_CS1 is coupled between the source terminal of the PMOS transistor MP1 and the common mode control circuit 410, and the PMOS transistor M_CS2 is coupled between the source terminal of the PMOS transistor MP2 and the common mode control circuit 410. The PMOS transistors M_CS1 and M_CS2 are operated as current sources for supplying currents to the transistors MP1, MN1, MP2 and MN2. The current sources CS1 and CS2 correspondingly sink currents from the transistors MP1, MN1, MP2 and MN2.

The common mode control circuit 410 includes an operational amplifier 412 and two common mode feedback resistors RCM1 and RCM2. The common mode feedback resistor RCM1 is coupled between the drain terminal of the PMOS transistor MP1, the drain terminal of the NMOS transistor MN1, and an input terminal of the operational amplifier 412. The common mode feedback resistor RCM2 is coupled between the drain terminal of the PMOS transistor MP2, the drain terminal of the NMOS transistor MN2, and the input terminal of the operational amplifier 412. The operational amplifier 412 may further receive a reference voltage VREF1 through another input terminal. In general, the common mode feedback resistors RCM1 and RCM2 may be designed to have identical resistance values, and thus the common mode voltage of the intermediate signals VM+ and VM− is controlled to be equal to the reference voltage VREF1. Through appropriate setting of the reference voltage VREF1, the intermediate signals VM+ and VM− are allowed to swing at the well-controlled level of the reference voltage VREF1 irrespective of the voltages of the differential input signals VIN+ and VIN−, so as to maintain the gain linearity.

Continuously referring to FIG. 4, the feedback stage 306 includes two PMOS transistors MP3 and MP4 and two NMOS transistors MN3 and MN4 used for signal transmissions, and also includes a pair of PMOS transistors M_CS3 and M_CS4, a pair of current sources CS3 and CS4, and two source degeneration resistors RS_FB1 and RS_FB2, as similar to the structure of the gain stage 302. In detail, the gate terminal of the PMOS transistor MP3 and the gate terminal of the NMOS transistor MN3 are connected together to receive the output signal VO+, and the gate terminal of the PMOS transistor MP4 and the gate terminal of the NMOS transistor MN4 are connected together to receive the output signal VO−. In addition, the drain terminal of the PMOS transistor MP3 and the drain terminal of the NMOS transistor MN3 are connected together to output the intermediate signal VM−, and the drain terminal of the PMOS transistor MP4 and the drain terminal of the NMOS transistor MN4 are connected together to output the intermediate signal VM+. The source terminals of the PMOS transistors MP3 and MP4 are further connected to the source degeneration resistor RS_FB1, and the source terminals of the NMOS transistors MN3 and MN4 are further connected to the source degeneration resistor RS_FB2. The PMOS transistors M_CS3 and M_CS4 are also operated as current sources, which along with the current sources CS3 and CS4 are configured to supply currents to the transistors MP3, MN3, MP4 and MN4.

With the all-CMOS process, all of the transistors in the gain stage 302 and the feedback stage 306, including those used for implementing the current sources CS1-CS4 and the operational amplifier 412, are CMOS transistors, where the usage of BJTs are avoided. The process complexity and related circuit cost may be reduced accordingly.

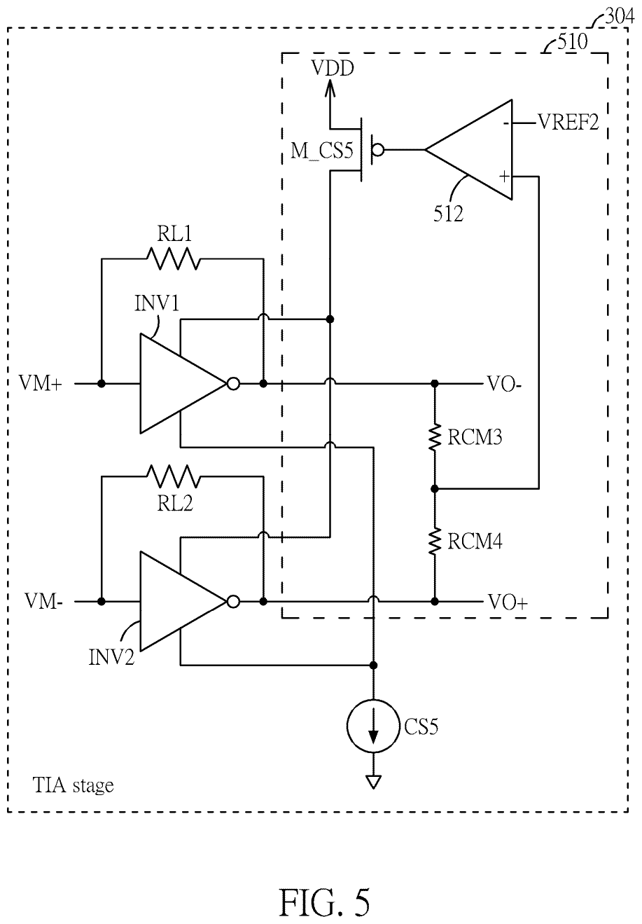

FIG. 5 illustrates a detailed implementation of the TIA stage 304 according to an embodiment of the present invention. Referring to FIG. 5 along with FIG. 3, the TIA stage 304 is configured to receive the intermediate signals VM+ and VM− and output the output signals VO+ and VO−. The TIA stage 304 includes two inverters INV1 and INV2, two load resistors RL1 and RL2, a current source CS5, and a common mode control circuit 510. The common mode control circuit 510 includes an operational amplifier 512, a PMOS transistor M_CS5 and two common mode feedback resistors RCM3 and RCM4. As shown in FIG. 5, the inverter INV1 is coupled between the positive input terminal and the negative output terminal of the TIA stage 304, to convert the intermediate signal VM+ into the output signal VO−, and the load resistor RL1 may be connected with the inverter INV1 in parallel. The inverter INV2 is coupled between the negative input terminal and the positive output terminal of the TIA stage 304, to convert the intermediate signal VM− into the output signal VO+, and the load resistor RL2 may be connected with the inverter INV2 in parallel. The inverters INV1 and INV2 may further be coupled to the PMOS transistor M_CS5 and the current source CS5, to receive current supply from the PMOS transistor M_CS5 and the current source CS5.

In the common mode control circuit 510, the common mode feedback resistor RCM3 is coupled between the output terminal of the inverter INV1 and an input terminal of the operational amplifier 512, and the common mode feedback resistor RCM4 is coupled between the output terminal of the inverter INV2 and the input terminal of the operational amplifier 512. The operational amplifier 512 may further receive a reference voltage VREF2 through another input terminal. Similarly, the common mode feedback resistors RCM3 and RCM4 may be designed to have identical resistance values, and thus the common mode voltage of the output signals VO+ and VO− is controlled to be equal to the reference voltage VREF2. Through appropriate setting of the reference voltage VREF2, the output signals VO+ and VO− are allowed to swing at the well-controlled level of the reference voltage VREF2, which will not be influenced by the level of the supply voltage VDD, allowing a wide range of the supply voltage VDD.

In an exemplary embodiment, the reference voltage VREF2 may be equal to 0.8V, and thus the output signals VO+ and VO− are differential signals swing on the 0.8V level. In such a situation, the output signals VO+ and VO− may be kept on the desired level regardless of the level of the supply voltage VDD. Therefore, the supply voltage VDD may have a wide range such as from 1.8V to 3.3V. In addition, the TIA stage 304 may isolate the output nodes from the intermediate nodes of the VGA 204. Therefore, a large signal swing may appear on the output signals VO+ and VO− at the output nodes, while the signal swing on the intermediate nodes may be stabilized and well controlled by the common mode control circuit 410. In other words, the intermediate signals VM+ and VM− between the gain stage 302 and the TIA stage 304 will not need to have a large signal swing. Therefore, even if the VGA 204 has a larger input swing, the transistors MP1, MN1, MP2 and MN2 in the gain stage 302 may still be operated in the saturation region, thereby achieving higher signal linearity.

Therefore, based on the circuit structure shown in FIGS. 4 and 5, the gain of the VGA 204 may be calculated as:

$$Gain = ( \frac{{g}_{m p}}{1 + {g}_{m p} {R}_{S 1}} + \frac{{g}_{m n}}{1 + {g}_{m n} {R}_{S 2}} ) \times {R}_{L} ; \qquad ( 2 )$$

where gₘₚ is the transconductance value of the PMOS transistors MP1 and MP2, gₘₙ is the transconductance value of the NMOS transistors MN1 and MN2, R_{S1} is the resistance value of the source degeneration resistor RS_G1, R_{S2} is the resistance value of the source degeneration resistor RS_G2, and R_{L} is the resistance value of the load resistors RL1 and RL2 in the TIA stage 304. Assuming that gₘₚ is equal to gₘₘ and that R_{S1} is equal to R_{S2}, Equation (2) may be rearranged as:

$$Gain = 2 \times ( \frac{{g}_{m n}}{1 + {g}_{m n} {R}_{S 2}} ) \times {R}_{L} . \qquad ( 3 )$$

Comparing Equation (3) with Equation (1), it can be seen that the gain of the VGA 204 proposed in the present invention may be twice that of the general VGA implemented with the BiCMOS process if these two VGAs have the same transconductance values and resistance values. Although the transconductance of the CMOS device is usually smaller than the transconductance of the BJT device used in the general VGA, the combination of high-side PMOS transistors MP1 and MP2 and low-side NMOS transistors MN1 and MN2 in the VGA 204 will complement the transconductance difference, so as to satisfy the high gain requirement of the re-driver circuit.

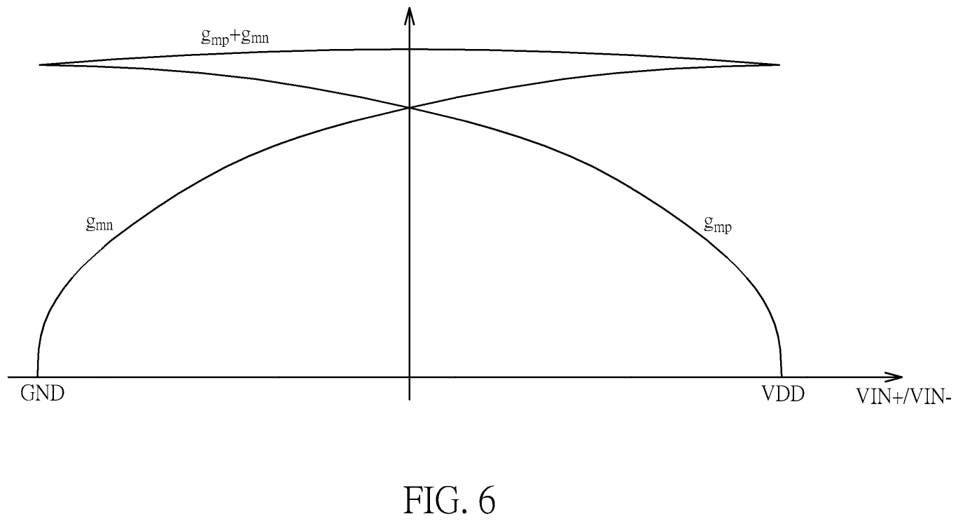

The combination of the high-side PMOS transistors MP1 and MP2 and the low-side NMOS transistors MN1 and MN2 may also improve the linearity of signal swing. FIG. 6 illustrates the transconductance value gₘₚ of the PMOS transistors MP1 and MP2 and the transconductance value gₘₙ of the NMOS transistors MN1 and MN2 over a voltage range of the input signals VIN+ and VIN−, which may be between the ground voltage GND and the supply voltage VDD. As shown in FIG. 6, the NMOS transistors MN1 and MN2 provide an optimal operation range with a higher gain in higher voltages closer to the supply voltage VDD since they have a higher transconductance value gₘₙ in higher voltages, while the PMOS transistors MP1 and MP2 provide an optimal operation range with a higher gain in lower voltages closer to the ground voltage GND since they have a higher transconductance value gₘₚ in lower voltages. Therefore, their combination (i.e., gₘₚ+gₘₙ) may achieve a high and flat gain in a wide voltage range between the supply voltage VDD and the ground voltage GND, which means that the signals have a wide swing range with high linearity.

Note that the present invention aims at providing a novel VGA structure with the all-CMOS process that could be implemented in a re-driver. Those skilled in the art may make modifications and alterations accordingly. For example, in the above embodiments, those source degeneration resistors may be variable resistors which may be adjusted or tuned to achieve variable gain values. In another embodiment, one or some of the source degeneration resistors may be implemented with one or more fixed resistors. In addition, the design of the resistors and transistors does not serve to limit the scope of the present invention. For example, in one or some embodiments, the transistors MP1, MN1, MP2 and MN2 may be well designed to have desired transconductance values gₘₚ and gₘₘ, and the source degeneration resistors RS_G1 and RS_G2 may be designed to have the same or different resistance values, e.g., based on the values of Imp and gₘₙ, so as to achieve high and flat gain over a wide voltage swing range.

In one or some embodiments, if the VGA 204 is operated in a high speed application, the transistors for signal transmission are preferably implemented with low-voltage devices. The low-voltage devices may be core devices in a chip, which usually have a smaller withstand voltage and a higher operational speed. Therefore, the VGA 204 may be well designed to isolate the supply voltage VDD from the signal transmission transistors, allowing the supply voltage VDD to have a wide range which is not limited by the withstand voltage of the signal transmission transistors.

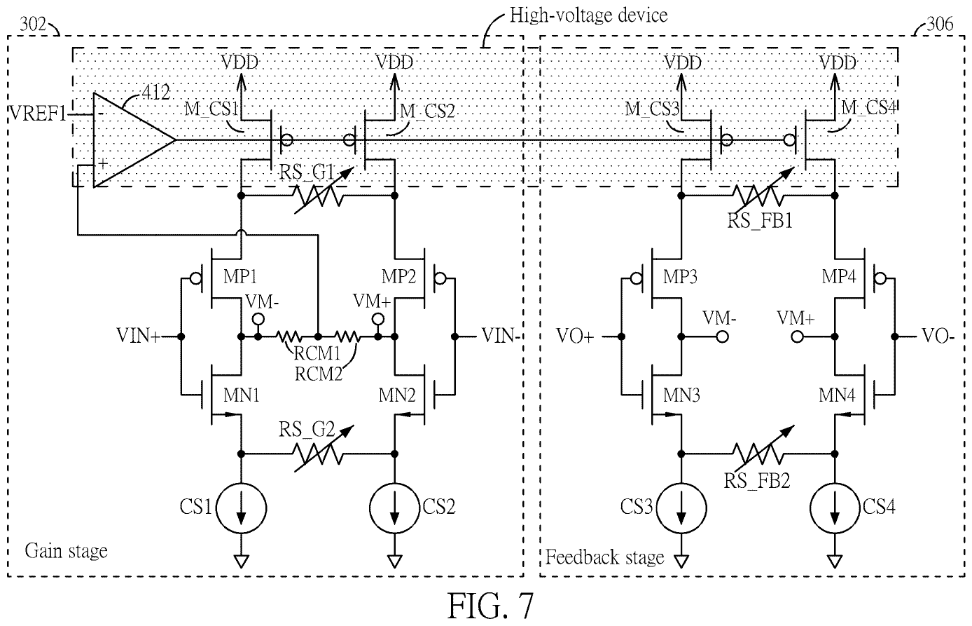

An exemplary implementation of the gain stage 302 and the feedback stage 306 associated with high-voltage and low-voltage devices is shown in FIG. 7, which illustrates the same circuit structure as that shown in FIG. 4, and thus the same signals and elements are denoted by the same symbols. As shown in FIG. 7, the operational amplifier 41 and the PMOS transistors M_CS1-M_CS4 are implemented with high-voltage devices, which may be I/O devices capable of withstanding a higher voltage such as 3.3V; hence, the VGA 204 may support the supply voltage VDD up to 3.3V. The signal transmission transistors, such as the transistors MP1, MN1, MP2 and MN2 in the gain stage 302 and the transistors MP3, MN3, MP4 and MN4 in the feedback stage 306, may be implemented with low-voltage devices, which may be core devices that could be operated at a higher speed to satisfy the requirements of high-speed transmission. In addition, in the gain stage 302, the reference voltage VREF1 may be well designed to control the common mode voltage of the intermediate signals VM+ and VM−, allowing the intermediate signals VM+ and VM− to swing at a level within the withstand voltage of the low-voltage devices.

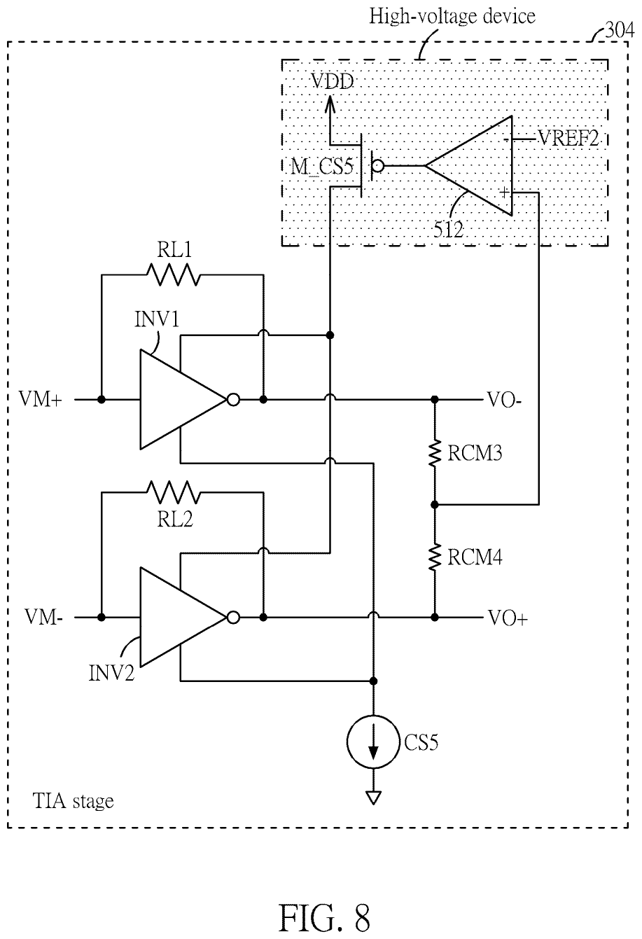

The TIA stage 304 may also be implemented in an appropriate manner to achieve the high-speed transmission, as shown in FIG. 8. The operational amplifier 512 and the PMOS transistor M_CS5 are implemented with high-voltage devices (e.g., I/O devices), to be capable of receiving the supply voltage VDD ranging from 1.8V to 3.3V. The transistors in the inverters INV1 and INV2 used to forward signals may be implemented with low-voltage devices (e.g., core devices) to achieve the high-speed signal transmission.

In the above embodiments, the high-voltage devices allow the VGA 204 to operate by receiving a higher supply voltage VDD, e.g., up to 3.3V. In another embodiment, if the supply voltage VDD received by the VGA is lower than 1.4V, the low-voltage devices may be feasible. For example, all transistors in the gain stage, the TIA stage and the feedback stage may be implemented with core voltages, and thus the circuit area and circuit cost may further be reduced.

To sum up, the present invention provides a novel VGA structure implemented with the all-CMOS process where no BJT is used, and thus the circuit may not need large headroom for the BJTs. This allows the VGA to support a wide range of supply voltage VDD, which is superior to the VGAs implemented in the BiCMOS process. In addition, by using the high-side PMOS transistors connected with the low-side NMOS transistors to implement the signal transmission transistors, high gain and high linearity may be achieved, to complement the drawbacks of lower transconductance of the CMOS devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A gain amplifier comprising:
a gain stage, comprising:
a first resistor;
a second resistor;
a first PMOS transistor, having a first terminal connected to the first resistor, a second terminal, and a gate terminal;
a first NMOS transistor, having a first terminal connected to the second resistor, a second terminal connected to the second terminal of the first PMOS transistor, and a gate terminal connected to the gate terminal of the first PMOS transistor;
a second PMOS transistor, having a first terminal connected to the first resistor, a second terminal, and a gate terminal; and
a second NMOS transistor, having a first terminal connected to the second resistor, a second terminal connected to the second terminal of the second PMOS transistor, and a gate terminal connected to the gate terminal of the second PMOS transistor;
a transimpedance amplifier (TIA) stage, coupled to the gain stage; and
a feedback stage, coupled to the gain stage and the TIA stage.

2. The gain amplifier of claim 1, wherein the gate terminal of the first PMOS transistor and the gate terminal of the first NMOS transistor are configured to receive a first input signal, and the gate terminal of the second PMOS transistor and the gate terminal of the second NMOS transistor are configured to receive a second input signal.

3. The gain amplifier of claim 1, wherein a positive input terminal of the TIA stage is coupled to a negative output terminal of the gain stage, and a negative input terminal of the TIA stage is coupled to a positive output terminal of the gain stage.

4. The gain amplifier of claim 1, wherein a positive input terminal of the feedback stage is coupled to a positive output terminal of the TIA stage, a negative input terminal of the feedback stage is coupled to a negative output terminal of the TIA stage, a positive output terminal of the feedback stage is coupled to a negative input terminal of the TIA stage, and a negative output terminal of the feedback stage is coupled to a positive input terminal of the TIA stage.

5. The gain amplifier of claim 1, wherein the feedback stage comprises:
a third resistor;
a fourth resistor;
a third PMOS transistor, having a first terminal connected to the third resistor, a second terminal, and a gate terminal;
a third NMOS transistor, having a first terminal connected to the fourth resistor, a second terminal connected to the second terminal of the third PMOS transistor, and a gate terminal connected to the gate terminal of the third PMOS transistor;
a fourth PMOS transistor, having a first terminal connected to the third resistor, a second terminal, and a gate terminal; and
a fourth NMOS transistor, having a first terminal connected to the fourth resistor, a second terminal connected to the second terminal of the fourth PMOS transistor, and a gate terminal connected to the gate terminal of the fourth PMOS transistor.

6. The gain amplifier of claim 1, wherein the gain stage further comprises:
a first common mode control circuit, comprising:
an operational amplifier;
a fifth resistor, coupled between the second terminal of the first PMOS transistor, the second terminal of the first NMOS transistor, and the operational amplifier; and
a sixth resistor, coupled between the second terminal of the second PMOS transistor, the second terminal of the second NMOS transistor, and the operational amplifier.

7. The gain amplifier of claim 6, wherein the gain stage further comprises:
a fifth PMOS transistor, coupled to the first terminal of the first PMOS transistor and the first common mode control circuit; and
a sixth PMOS transistor, coupled to the first terminal of the second PMOS transistor and the first common mode control circuit.

8. The gain amplifier of claim 7, wherein the fifth PMOS transistor, the sixth PMOS transistor and the operational amplifier are implemented with high-voltage devices, and the first PMOS transistor, the first NMOS transistor, the second PMOS transistor and the second NMOS transistor are implemented with low-voltage devices.

9. The gain amplifier of claim 1, wherein the TIA stage comprises:
a second common mode control circuit, comprising:
an operational amplifier; and
a control transistor, coupled to the operational amplifier;
a first inverter, coupled between a positive input terminal of the TIA stage, a negative output terminal of the TIA stage, and the second common mode control circuit; and
a second inverter, coupled between a negative input terminal of the TIA stage, a positive output terminal of the TIA stage, and the second common mode control circuit.

10. A re-driver circuit comprising:
an equalizer;
a gain amplifier, coupled to the equalizer, comprising:
a gain stage, comprising:
a first resistor;
a second resistor;
a first PMOS transistor, having a first terminal connected to the first resistor, a second terminal, and a gate terminal;
a first NMOS transistor, having a first terminal connected to the second resistor, a second terminal connected to the second terminal of the first PMOS transistor, and a gate terminal connected to the gate terminal of the first PMOS transistor;
a second PMOS transistor, having a first terminal connected to the first resistor, a second terminal, and a gate terminal; and
a second NMOS transistor, having a first terminal connected to the second resistor, a second terminal connected to the second terminal of the second PMOS transistor, and a gate terminal connected to the gate terminal of the second PMOS transistor;
a transimpedance amplifier (TIA) stage, coupled to the gain stage; and
a feedback stage, coupled to the gain stage and the TIA stage; and
a transmitter, coupled to the gain amplifier.
